(19) United States
(12) Patent Application Publication
(10) Pub. No.: US 2024/0063202 A1
(43) Pub. Date: Feb. 22, 2024

(54) PACKAGE ARCHITECTURE WITH INTEGRATED CAPACITORS IN QUASI-MONOLITHIC CHIP LAYERS

(71) Applicant: Intel Corporation, Santa Clara, CA (US)

(72) Inventors: Adel A. Elsherbini, Chandler, AZ (US); Thomas Sounart, Chandler, AZ (US); Henning Braunisch, Phoenix, AZ (US); William J. Lambert, Chandler, AZ (US); Kaladhar Radhakrishnan, Chandler, AZ (US); Shawna M. Liff, Scottsdale, AZ (US); Mohammad Enamul Kabir, Portland, OR (US); Omkar G. Karhade, Chandler, AZ (US); Kimin Jun, Portland, OR (US); Johanna M. Swan, Scottsdale, AZ (US)

(73) Assignee: Intel Corporation, Santa Clara, CA (US)

(21) Appl. No.: 17/820,968

(22) Filed: Aug. 19, 2022

(51) Int. Cl. H01L 25/18; H01L 23/522; H01L 49/02; H01L 23/00; H01L 23/498; H01L 23/48; H01L 25/00

(52) U.S. Cl. CPC H01L 25/18; H01L 23/5223; H01L 28/90; H01L 24/08; H01L 23/49811; H01L 23/481; H01L 25/50; H01L 24/80; H01L 2224/08145; H01L 2224/80895; H01L 2224/80896

(57) ABSTRACT

Embodiments of a microelectronic assembly comprise: a plurality of layers of IC dies in a dielectric material, adjacent layers in the plurality of layers being coupled together by first interconnects having a pitch of less than 10 micrometers between adjacent first interconnects; a package substrate coupled to a first side of the plurality of layers by second interconnects; a support structure coupled to a second side of the plurality of layers by third interconnects, the second side being opposite to the first side; and capacitors in at least the plurality of layers or the support structure. The capacitors are selected from at least planar capacitors, deep trench capacitors and via capacitors.

### TECHNICAL FIELD

The present disclosure relates to techniques, methods, and apparatus directed to a package architecture with integrated capacitors in quasi-monolithic chip layers.

### BACKGROUND

Electronic circuits when commonly fabricated on a wafer of semiconductor material, such as silicon, are called integrated circuits (ICs). The wafer with such ICs is typically cut into numerous individual dies. The dies may be packaged into an IC package containing one or more dies along with other electronic components such as resistors, capacitors, and inductors. The IC package may be integrated onto an electronic system, such as a consumer electronic system, or servers, such as mainframes.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, and not by way of limitation, in the figures of the accompanying drawings.

FIG. 1A is a schematic cross-sectional view of an example microelectronic assembly according to some embodiments of the present disclosure.

FIG. 1B is a schematic cross-sectional view of a portion of the example microelectronic assembly of FIG. 1A.

FIG. 2 is a schematic cross-sectional view of another example microelectronic assembly according to some embodiments of the present disclosure.

FIG. 3 is a schematic cross-sectional view of yet another example microelectronic assembly according to some embodiments of the present disclosure.

FIG. 4 is a schematic cross-sectional view of yet another example microelectronic assembly according to some embodiments of the present disclosure.

FIG. 5 is a schematic cross-sectional view of yet another example microelectronic assembly according to some embodiments of the present disclosure.

FIGS. 6A-6F are schematic cross-sectional views of a portion of a microelectronic assembly according to various embodiments of the present disclosure.

FIG. 7 is a schematic view of an example configuration of capacitors in a microelectronic assembly according to various embodiments of the present disclosure.

FIG. 8 is a schematic view of another example configuration of capacitors in a microelectronic assembly according to various embodiments of the present disclosure.

FIG. 9 is a schematic view of yet another example configuration of capacitors in a microelectronic assembly according to various embodiments of the present disclosure.

FIG. 10 is a schematic view of yet another example configuration of capacitors in a microelectronic assembly according to various embodiments of the present disclosure.

FIG. 11 is a schematic flow diagram listing example operations that may be associated with fabricating a microelectronic assembly according to some embodiments of the present disclosure.

FIG. 12 is a cross-sectional view of a device package that includes one or more microelectronic assemblies in accordance with any of the embodiments disclosed herein.

FIG. 13 is a cross-sectional side view of a device assembly that includes one or more microelectronic assemblies in accordance with any of the embodiments disclosed herein.

FIG. 14 is a block diagram of an example computing device that includes one or more microelectronic assemblies in accordance with any of the embodiments disclosed herein.

### DETAILED DESCRIPTION

### Overview

For purposes of illustrating IC packages described herein, it is important to understand phenomena that may come into play during assembly and packaging of ICs. The following foundational information may be viewed as a basis from which the present disclosure may be properly explained. Such information is offered for purposes of explanation only and, accordingly, should not be construed in any way to limit the broad scope of the present disclosure and its potential applications.

Advances in semiconductor processing and logic design have permitted an increase in the amount of logic circuits that may be included in processors and other IC devices. As a result, many processors now have multiple cores that are monolithically integrated on a single die. Generally, these types of monolithic ICs are also described as planar since they take the form of a flat surface and are typically built on a single silicon wafer made from a monocrystalline silicon boule. The typical manufacturing process for such monolithic ICs is called a planar process, allowing photolithography, etching, heat diffusion, oxidation, and other such processes to occur on the surface of the wafer, such that active circuit elements (e.g., transistors and diodes) are formed on the planar surface of the silicon wafer.

Current technologies permit hundreds and thousands of such active circuit elements to be formed on a single die so that numerous logic circuits may be enabled thereon. In such monolithic dies, the manufacturing process must be optimized for all the circuits equally, resulting in trade-offs between different circuits. In addition, because of the limitation of having to place circuits on a planar surface, some circuits are farther apart from some others, resulting in decreased performance such as longer delays. The manufacturing yield may also be severely impacted because the entire die may have to be discarded if even one circuit is malfunctional.

One solution to overcome such negative impacts of monolithic dies is to disaggregate the circuits into smaller dies (e.g., chiplets. tiles) electrically coupled by interconnect bridges. The smaller dies are part of an assembly of interconnected dies that together form a complete IC in terms of application and/or functionality, such as a memory chip, microprocessor, microcontroller, commodity IC (e.g., chip used for repetitive processing routines, simple tasks, application specific IC, etc.), and system-on-a-chip (SoC). In other words, the individual dies are connected to create the functionalities of a monolithic IC. By using separate dies, each individual die can be designed and manufactured optimally for a particular functionality. For example, a processor core that contains logic circuits might aim for performance, and thus might require a very speed-optimized layout. This has different manufacturing requirements compared to a USB controller, which is built to meet certain universal serial bus (USB) standards, rather than for processing speed. Thus, by having different parts of the overall design separated into different dies, each one optimized in terms of design and manufacturing, the overall yield and cost of the combined die solution may be improved.

The connectivity between these dies is achievable by many ways. For example, in 2.5D packaging solutions, a silicon interposer and through-silicon vias (TSVs) connect dies at silicon interconnect speed in a minimal footprint. In another example, a silicon bridge embedded under the edges of two interconnecting dies facilitates electrical coupling between them. In a three-dimensional (3D) architecture, the dies are stacked one above the other, creating a smaller footprint overall. Typically, the electrical connectivity and mechanical coupling in such 3D architecture is achieved using TSVs and high pitch solder-based bumps (e.g., C2 interconnections). The bridge and the 3D stacked architecture may also be combined to allow for top-packaged chips to communicate with other chips horizontally using the bridge and vertically, using Through-Mold Vias (TMVs) which are typically larger than TSVs. However, these current interconnect technologies use solder or its equivalent for connectivity, with consequent low vertical and horizontal interconnect density.

One way to mitigate low vertical interconnect density is to use an interposer, which improves vertical interconnect density but suffers from low lateral interconnect density if the base wafer of the interposer is passive. In a general sense, an “interposer” is commonly used to refer to a base piece of silicon that interconnects two dies. By including active circuit elements in the interposer, lateral speeds may be improved, but it requires more expensive manufacturing processes, in particular when a large base die is used to interconnect smaller dies. Additionally, not all interfaces require fine pitch connections which may lead to additional manufacturing and processing overheads without the benefits of the fine pitch.

High performance compute systems require high density capacitors to address large power transients and/or enable better power conversion, for example, through co-integrated buck or switched cap regulators. Two types of capacitors are typically used to provide high density capacitance: on-die integrated capacitors and package or interposed integrated capacitors. On-die integrated capacitors have high density but are limited to the die area. It is also challenging to implement them in some technology nodes. Besides, they cannot support high-area structures like deep trench capacitors. Because they can be effectively implemented with high density at low voltage, they are suitable for low voltage regulator (VR) output decoupling. In some devices, on-die capacitance is typically used for VR output decoupling, and other capacitors elsewhere in the package are used for VR input decoupling. Package or interposer-integrated capacitors can have large area and are independent of on-die technology. However, package-integrated capacitors are typically lower density due to package manufacturing requirements. Interposer capacitors such as deep trench capacitors offer higher density but they require the added cost of a silicon or glass interposer and may have added power and signaling penalty as power and signaling have to go through TSVs with their associated parasitics.

In this regard, techniques for integrating capacitors in hybrid bonding architectures such as quasi-monolithic hierarchically integrated packaging architecture represents an opportunity to further improve the performance of these architectures while utilizing existing infrastructure and manufacturing capabilities. The quasi-monolithic hierarchically integrated packaging architecture includes recursively coupled plurality of IC dies in microelectronic assemblies of a processing system. The plurality of IC dies may comprise active dies and/or passive dies, and at least a portion of the plurality of dies are coupled using high density interconnects.

Accordingly, embodiments of a microelectronic assembly disclosed herein comprise a plurality of layers of IC dies in a dielectric material, adjacent layers in the plurality of layers being coupled together by first interconnects having a pitch of less than 10 micrometers between adjacent first interconnects; a package substrate coupled to a first side of the plurality of layers by second interconnects; a support structure coupled to a second side of the plurality of layers by third interconnects, the second side being opposite to the first side; and capacitors in at least the plurality of layers or the support structure. The capacitors are selected from at least planar capacitors, deep trench capacitors and via capacitors. The quasi-monolithic packaging architecture with capacitors as in the embodiments described herein can enable better power delivery and transient support with higher capacitance than in traditional on-die or package/interposer-integrated capacitors.

Each of the structures, assemblies, packages, methods, devices, and systems of the present disclosure may have several innovative aspects, no single one of which is solely responsible for all the desirable attributes disclosed herein. Details of one or more implementations of the subject matter described in this specification are set forth in the description below and the accompanying drawings.

In the following detailed description, various aspects of the illustrative implementations may be described using terms commonly employed by those skilled in the art to convey the substance of their work to others skilled in the art.

The terms “circuit” and “circuitry” mean one or more passive and/or active electrical and/or electronic components that are arranged to cooperate with one another to provide a desired function. The terms also refer to analog circuitry, digital circuitry, hard wired circuitry, programmable circuitry, microcontroller circuitry and/or any other type of physical hardware electrical and/or electronic component.

The term “integrated circuit” means a circuit that is integrated into a monolithic semiconductor or analogous material.

In some embodiments, the IC dies disclosed herein may comprise substantially monocrystalline semiconductors, such as silicon or germanium, as a base material (e.g., substrate, body) on which integrated circuits are fabricated with traditional semiconductor processing methods. The semiconductor base material may include, for example, N-type pr P-type materials. Dies may include, for example, a crystalline base material formed using a bulk silicon (or other bulk semiconductor material) or a silicon-on-insulator (SOI) structure. In some other embodiments, the base material of one or more of the IC dies may comprise alternate materials, which may or may not be combined with silicon, that include but are not limited to germanium, indium antimonide, lead telluride, indium arsenide, indium phosphide, gallium arsenide, indium gallium arsenide, gallium antimonide, or other combinations of group III-N, group III-V, group II-VI, or group IV materials. In yet other embodiments, the base material may comprise compound semiconductors, for example, with a first sub-lattice of at least one element from group III of the periodic table (e.g., Al, Ga, In), and a second sub-lattice of at least one element of group V of the periodic table (e.g., P, As, Sb). In yet other embodiments, the base material may comprise an intrinsic IV or III-V semiconductor material or alloy, not intentionally doped with any electrically active impurity; in alternate embodiments, nominal impurity dopant levels may be present. In still other embodiments, dies may comprise a non-crystalline material, such as polymers; for example, the base material may comprise silica-filled epoxy. In other embodiments, the base material may comprise high mobility oxide semiconductor material, such as tin oxide, antimony oxide, indium oxide, indium tin oxide, titanium oxide, zinc oxide, indium zinc oxide, indium gallium zinc oxide (IGZO), gallium oxide, titanium oxynitride, ruthenium oxide, or tungsten oxide. In general, the base material may include one or more of tin oxide, cobalt oxide, copper oxide, antimony oxide, ruthenium oxide, tungsten oxide, zinc oxide, gallium oxide, titanium oxide, indium oxide, titanium oxynitride, indium tin oxide, indium zinc oxide, nickel oxide, niobium oxide, copper peroxide, IGZO, indium telluride, molybdenite, molybdenum diselenide, tungsten diselenide, tungsten disulfide, N- or P-type amorphous or polycrystalline silicon, germanium, indium gallium arsenide, silicon germanium, gallium nitride, aluminum gallium nitride, indium phosphide, and black phosphorus, each of which may possibly be doped with one or more of gallium, indium, aluminum, fluorine, boron, phosphorus, arsenic, nitrogen, tantalum, tungsten, and magnesium, etc. Although a few examples of the material for dies are described here, any material or structure that may serve as a foundation (e.g., base material) upon which IC circuits and structures as described herein may be built falls within the spirit and scope of the present disclosure.

Unless described otherwise, IC dies described herein include one or more IC structures (or, simply, “ICs”) implementing (i.e., configured to perform) certain functionality. In one such example, the term “memory die” may be used to describe a die that includes one or more ICs implementing memory circuitry (e.g., ICs implementing one or more of memory devices, memory arrays, control logic configured to control the memory devices and arrays, etc.). In another such example, the term “compute die” may be used to describe a die that includes one or more ICs implementing logic/compute circuitry (e.g., ICs implementing one or more of I/O functions, arithmetic operations, pipelining of data, etc.).

In another example, the terms “package” and “IC package” are synonymous, as are the terms “die” and “IC die.” Note that the terms “chip,” “die,” and “IC die” are used interchangeably herein.

The term “insulating” means “electrically insulating,” the term “conducting” means “electrically conducting,” unless otherwise specified. With reference to optical signals and/or devices, components and elements that operate on or using optical signals, the term “conducting” can also mean “optically conducting.”

The terms “oxide,” “carbide,” “nitride,” etc. refer to compounds containing, respectively, oxygen, carbon, nitrogen, etc.

The term “high-k dielectric” refers to a material having a higher dielectric constant than silicon oxide, while the term “low-k dielectric” refers to a material having a lower dielectric constant than silicon oxide.

The term “insulating material” or “insulator” (also called herein as “dielectric material” or “dielectric”) refers to solid materials (and/or liquid materials that solidify after processing as described herein) that are substantially electrically nonconducting. They may include, as examples and not as limitations, organic polymers and plastics, and inorganic materials such as ionic crystals, porcelain, glass, silicon, silicon oxide, silicon carbide, silicon carbonitride, silicon nitride, and alumina or a combination thereof. They may include dielectric materials, high polarizability materials, and/or piezoelectric materials. They may be transparent or opaque without departing from the scope of the present disclosure. Further examples of insulating materials are underfills and molds or mold-like materials used in packaging applications, including for example, materials used in organic interposers, package supports and other such components.

In various embodiments, elements associated with an IC may include, for example, transistors, diodes, power sources, resistors, capacitors, inductors, sensors, transceivers, receivers, antennas, etc. In various embodiments, elements associated with an IC may include those that are monolithically integrated within an IC, mounted on an IC, or those connected to an IC. The ICs described herein may be either analog or digital and may be used in a number of applications, such as microprocessors, optoelectronics, logic blocks, audio amplifiers, etc., depending on the components associated with the IC. The ICs described herein may be employed in a single IC die or as part of a chipset for executing one or more related functions in a computer.

In various embodiments of the present disclosure, transistors described herein may be field-effect transistors (FETs), e.g., MOSFETs. In many embodiments, an FET is a four-terminal device. In silicon-on-insulator, or nanoribbon, or gate all-around (GAA) FET, the FET is a three-terminal device that includes source, drain, and gate terminals and uses electric field to control current flowing through the device. A FET typically includes a channel material, a source region and a drain regions provided in and/or over the channel material, and a gate stack that includes a gate electrode material, alternatively referred to as a “work function” material, provided over a portion of the channel material (the “channel portion”) between the source and the drain regions, and optionally, also includes a gate dielectric material between the gate electrode material and the channel material.

In a general sense, an “interconnect” refers to any element that provides a physical connection between two other elements. For example, an electrical interconnect provides electrical connectivity between two electrical components, facilitating communication of electrical signals between them; an optical interconnect provides optical connectivity between two optical components, facilitating communication of optical signals between them. As used herein, both electrical interconnects and optical interconnects are comprised in the term “interconnect.” The nature of the interconnect being described is to be understood herein with reference to the signal medium associated therewith. Thus, when used with reference to an electronic device, such as an IC that operates using electrical signals, the term “interconnect” describes any element formed of an electrically conductive material for providing electrical connectivity to one or more elements associated with the IC or/and between various such elements. In such cases, the term “interconnect” may refer to both conductive traces (also sometimes referred to as “lines,” “wires,” “metal lines” or “trenches”) and conductive vias (also sometimes referred to as “vias” or “metal vias”). Sometimes, electrically conductive traces and vias may be referred to as “conductive traces” and “conductive vias”, respectively, to highlight the fact that these elements include electrically conductive materials such as metals. Likewise, when used with reference to a device that operates on optical signals as well, such as a photonic IC (PIC), “interconnect” may also describe any element formed of a material that is optically conductive for providing optical connectivity to one or more elements associated with the PCI. In such cases, the term “interconnect” may refer to optical waveguides, including optical fiber, optical splitters, optical combiners, optical couplers, and optical vias.

The term “waveguide” refers to any structure that acts to guide the propagation of light from one location to another location typically through a substrate material such as silicon or glass. In various examples, waveguides can be formed from silicon, doped silicon, silicon nitride, glasses such as silica (e.g., silicon dioxide or SiO₂), borosilicate (e.g., 70-80 wt % SiO₂, 7-13 wt % of B₂O₃, 4-8 wt % Na₂O or K₂O, and 2-8 wt % of Al₂O₃) and so forth. Waveguides may be formed using various techniques including but not limited to forming waveguides in situ. For example, in some embodiments, waveguides may be formed in situ in glass using low temperature glass-to-glass bonding or by laser direct writing. Waveguides formed in situ may have lower loss characteristics.

The term “conductive trace” may be used to describe an electrically conductive element isolated by an insulating material. Within IC dies, such insulating material comprises interlayer low-k dielectric that is provided within the IC die. Within package substrates, and printed circuit boards (PCBs) such insulating material comprises organic materials such as Ajinomoto Buildup Film (ABF), polyimides, or epoxy resin. Such conductive lines are typically arranged in several levels, or several layers, of metallization stacks.

The term “conductive via” may be used to describe an electrically conductive element that interconnects two or more conductive lines of different levels of a metallization stack. To that end, a via may be provided substantially perpendicularly to the plane of an IC die/chip or a support structure over which an IC structure is provided and may interconnect two conductive lines in adjacent levels or two conductive lines in non-adjacent levels.

The term “package substrate” may be used to describe any substrate material that facilitates the packaging together of any collection of semiconductor dies and/or other electrical components such as passive electrical components. As used herein, a package substrate may be formed of any material including, but not limited to, insulating materials such as resin impregnated glass fibers (e.g., PCB or Printed Wiring Boards (PWB)), glass, ceramic, silicon, silicon carbide, etc. In addition, as used herein, a package substrate may refer to a substrate that includes buildup layers (e.g., ABF layers).

The term “metallization stack” may be used to refer to a stack of one or more interconnects for providing connectivity to different circuit components of an IC die/chip and/or a package substrate.

As used herein, the term “pitch” of interconnects refers to a center-to-center distance between adjacent interconnects.

In context of a stack of dies coupled to one another or in context of a die coupled to a package substrate, the term “interconnect” may also refer to, respectively, die-to-die (DTD) interconnects and die-to-package substrate (DTPS) interconnects. DTD interconnects may also be referred to as first-level interconnects (FLI). DTPS interconnects may also be referred to as Second-Level Interconnects (SLI).

Although not specifically shown in all of the present illustrations in order to not clutter the drawings, when DTD or DTPS interconnects are described, a surface of a first die may include a first set of conductive contacts, and a surface of a second die or a package substrate may include a second set of conductive contacts. One or more conductive contacts of the first set may then be electrically and mechanically coupled to some of the conductive contacts of the second set by the DTD or DTPS interconnects.

In some embodiments, the pitch of the DTD interconnects may be different from the pitch of the DTPS interconnects, although, in other embodiments, these pitches may be substantially the same.

The DTPS interconnects disclosed herein may take any suitable form. In some embodiments, a set of DTPS interconnects may include solder (e.g., solder bumps or balls that are subject to a thermal reflow to form the DTPS interconnects). DTPS interconnects that include solder may include any appropriate solder material, such as lead/tin, tin/bismuth, eutectic tin/silver, ternary tin/silver/copper, eutectic tin/copper, tin/nickel/copper, tin/bismuth/copper, tin/indium/copper, tin/zinc/indium/bismuth, or other alloys. In some embodiments, a set of DTPS interconnects may include an anisotropic conductive material, such as an anisotropic conductive film or an anisotropic conductive paste. An anisotropic conductive material may include conductive materials dispersed in a non-conductive material. In some embodiments, an anisotropic conductive material may include microscopic conductive particles embedded in a binder or a thermoset adhesive film (e.g., a thermoset biphenyl-type epoxy resin, or an acrylic-based material). In some embodiments, the conductive particles may include a polymer and/or one or more metals (e.g., nickel or gold). For example, the conductive particles may include nickel-coated gold or silver-coated copper that is in turn coated with a polymer. In another example, the conductive particles may include nickel. When an anisotropic conductive material is uncompressed, there may be no conductive pathway from one side of the material to the other. However, when the anisotropic conductive material is adequately compressed (e.g., by conductive contacts on either side of the anisotropic conductive material), the conductive materials near the region of compression may contact each other so as to form a conductive pathway from one side of the film to the other in the region of compression.

The DTD interconnects disclosed herein may take any suitable form. In some embodiments, some or all of the DTD interconnects in a microelectronic assembly or an IC package as described herein may be metal-to-metal interconnects (e.g., copper-to-copper interconnects, or plated interconnects). In such embodiments, the conductive contacts on either side of the DTD interconnect may be bonded together (e.g., under elevated pressure and/or temperature) without the use of intervening solder or an anisotropic conductive material. In some metal-to-metal interconnects, a dielectric material (e.g., silicon oxide, silicon nitride, silicon carbide) may be present between the metals bonded together (e.g., between copper pads or posts that provide the associated conductive contacts). In some embodiments, one side of a DTD interconnect may include a metal pillar (e.g., a copper pillar), and the other side of the DTD interconnect may include a metal contact (e.g., a copper contact) recessed in a dielectric. In some embodiments, a metal-to-metal interconnect (e.g., a copper-to-copper interconnect) may include a noble metal (e.g., gold) or a metal whose oxides are conductive (e.g., silver). In some embodiments, a metal-to-metal interconnect may include metal nanostructures (e.g., nanorods) that may have a reduced melting point. Metal-to-metal interconnects may be capable of reliably conducting a higher current than other types of interconnects; for example, some solder interconnects may form brittle intermetallic compounds when current flows, and the maximum current provided through such interconnects may be constrained to mitigate mechanical failure.

In some embodiments, the dies on either side of a set of DTD interconnects may be bare (e.g., unpackaged) dies.

In some embodiments, the DTD interconnects may include solder. For example, the DTD interconnects may include conductive bumps or pillars (e.g., copper bumps or pillars) attached to the respective conductive contacts by solder. In some embodiments, a thin cap of solder may be used in a metal-to-metal interconnect to accommodate planarity, and this solder may become an intermetallic compound during processing. In some embodiments, the solder used in some or all of the DTD interconnects may have a higher melting point than the solder included in some or all of the DTPS interconnects. For example, when the DTD interconnects in an IC package are formed before the DTPS interconnects are formed, solder-based DTD interconnects may use a higher-temperature solder (e.g., with a melting point above 200 degrees Celsius), while the DTPS interconnects may use a lower-temperature solder (e.g., with a melting point below 200 degrees Celsius). In some embodiments, a higher-temperature solder may include tin; tin and gold; or tin, silver, and copper (e.g., 96.5% tin, 3% silver, and 0.5% copper). In some embodiments, a lower-temperature solder may include tin and bismuth (e.g., eutectic tin bismuth), tin, silver, bismuth, indium, indium and tin, or gallium.

In some embodiments, a set of DTD interconnects may include an anisotropic conductive material, such as any of the materials discussed above for the DTPS interconnects. In some embodiments, the DTD interconnects may be used as data transfer lanes, while the DTPS interconnects may be used for power and ground lines, among others.

In microelectronic assemblies or IC packages as described herein, some or all of the DTD interconnects may have a finer pitch than the DTPS interconnects. In some embodiments, the DTPS interconnects disclosed herein may have a pitch between about 80 microns and 300 microns, while the DTD interconnects disclosed herein may have a pitch between about 0.5 microns and 100 microns, depending on the type of the DTD interconnects. An example of silicon-level interconnect density is provided by the density of some DTD interconnects. In some embodiments, the DTD interconnects may have too fine a pitch to couple to the package substrate directly (e.g., too fine to serve as DTPS interconnects). The DTD interconnects may have a smaller pitch than the DTPS interconnects due to the greater similarity of materials in the different dies on either side of a set of DTD interconnects than between a die and a package substrate on either side of a set of DTPS interconnects. In particular, the differences in the material composition of dies and package substrates may result in differential expansion and contraction of the die dies and package substrates due to heat generated during operation (as well as the heat applied during various manufacturing operations). To mitigate damage caused by this differential expansion and contraction (e.g., cracking, solder bridging, etc.), the DTPS interconnects in any of the microelectronic assemblies or IC packages as described herein may be formed larger and farther apart than DTD interconnects, which may experience less thermal stress due to the greater material similarity of the pair of dies on either side of the DTD interconnects.

It will be recognized that one more levels of underfill (e.g., organic polymer material such as benzotriazole, imidazole, polyimide, or epoxy) may be provided in an IC package described herein and may not be labeled in order to avoid cluttering the drawings. In various embodiments, the levels of underfill may comprise the same or different insulating materials. In some embodiments, the levels of underfill may comprise thermoset epoxies with silicon oxide particles; in some embodiments, the levels of underfill may comprise any suitable material that can perform underfill functions such as supporting the dies and reducing thermal stress on interconnects. In some embodiments, the choice of underfill material may be based on design considerations, such as form factor, size, stress, operating conditions, etc.; in other embodiments, the choice of underfill material may be based on material properties and processing conditions, such as cure temperature, glass transition temperature, viscosity and chemical resistance, among other factors; in some embodiments, the choice of underfill material may be based on both design and processing considerations.

In some embodiments, one or more levels of solder resist (e.g., epoxy liquid, liquid photoimageable polymers, dry film photoimageable polymers, acrylics, solvents) may be provided in an IC package described herein and may not be labeled or shown to avoid cluttering the drawings. Solder resist may be a liquid or dry film material including photoimageable polymers. In some embodiments, solder resist may be non-photoimageable.

The terms “substantially,” “close,” “approximately,” “near,” and “about,” generally refer to being within +/−20% of a target value (e.g., within +/−5% or 10% of a target value) based on the context of a particular value as described herein or as known in the art.

Terms indicating orientation of various elements, e.g., “coplanar,” “perpendicular,” “orthogonal,” “parallel,” or any other angle between the elements, generally refer to being within +/−5%-20% of a target value based on the context of a particular value as described herein or as known in the art.

The term “connected” means a direct connection (which may be one or more of a mechanical, electrical, and/or thermal connection) between the things that are connected, without any intermediary devices, while the term “coupled” means either a direct connection between the things that are connected, or an indirect connection through one or more passive or active intermediary devices.

The description uses the phrases “in an embodiment” or “in embodiments,” which may each refer to one or more of the same or different embodiments.

Furthermore, the terms “comprising,” “including,” “having,” and the like, as used with respect to embodiments of the present disclosure, are synonymous.

The disclosure may use perspective-based descriptions such as “above,” “below,” “top,” “bottom,” and “side”; such descriptions are used to facilitate the discussion and are not intended to restrict the application of disclosed embodiments.

The terms “over,” “under,” “between,” and “on” as used herein refer to a relative position of one material layer or component with respect to other layers or components. For example, one layer disposed over or under another layer may be directly in contact with the other layer or may have one or more intervening layers. Moreover, one layer disposed between two layers may be directly in contact with one or both of the two layers or may have one or more intervening layers. In contrast, a first layer described to be “on” a second layer refers to a layer that is in direct contact with that second layer. Similarly, unless explicitly stated otherwise, one feature disposed between two features may be in direct contact with the adjacent features or may have one or more intervening layers.

The term “dispose” as used herein refers to position, location, placement, and/or arrangement rather than to any particular method of formation.

The term “between,” when used with reference to measurement ranges, is inclusive of the ends of the measurement ranges.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). When used herein, the notation “A/B/C” means (A), (B), and/or (C).

Although certain elements may be referred to in the singular herein, such elements may include multiple sub-elements. For example, “an electrically conductive material” may include one or more electrically conductive materials. In another example, “a dielectric material” may include one or more dielectric materials.

Unless otherwise specified, the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner.

In the following detailed description, reference is made to the accompanying drawings that form a part hereof, and in which is shown, by way of illustration, embodiments that may be practiced. It is to be understood that other embodiments may be utilized, and structural or logical changes may be made without departing from the scope of the present disclosure. Therefore, the following detailed description is not to be taken in a limiting sense.

The accompanying drawings are not necessarily drawn to scale.

In the drawings, same reference numerals refer to the same or analogous elements/materials shown so that, unless stated otherwise, explanations of an element/material with a given reference numeral provided in context of one of the drawings are applicable to other drawings where element/materials with the same reference numerals may be illustrated. Further, the singular and plural forms of the labels may be used with reference numerals to denote a single one and multiple ones respectively of the same or analogous type, species, or class of element.

Furthermore, in the drawings, some schematic illustrations of example structures of various devices and assemblies described herein may be shown with precise right angles and straight lines, but it is to be understood that such schematic illustrations may not reflect real-life process limitations which may cause the features to not look so “ideal” when any of the structures described herein are examined using, e.g., images of suitable characterization tools such as scanning electron microscopy (SEM) images, transmission electron microscope (TEM) images, or non-contact profilometer. In such images of real structures, possible processing and/or surface defects could also be visible, e.g., surface roughness, curvature or profile deviation, pit or scratches, not-perfectly straight edges of materials, tapered vias or other openings, inadvertent rounding of corners or variations in thicknesses of different material layers, occasional screw, edge, or combination dislocations within the crystalline region(s), and/or occasional dislocation defects of single atoms or clusters of atoms. There may be other defects not listed here but that are common within the field of device fabrication and/or packaging.

Note that in the figures, various components (e.g., interconnects) are shown as aligned (e.g., at respective interfaces) merely for ease of illustration; in actuality, some or all of them may be misaligned. In addition, there may be other components, such as bond-pads, landing pads, metallization, etc. present in the assembly that are not shown in the figures to prevent cluttering. Further, the figures are intended to show relative arrangements of the components within their assemblies, and, in general, such assemblies may include other components that are not illustrated (e.g., various interfacial layers or various other components related to optical functionality, electrical connectivity, or thermal mitigation). For example, in some further embodiments, the assembly as shown in the figures may include more dies along with other electrical components. Additionally, although some components of the assemblies are illustrated in the figures as being planar rectangles or formed of rectangular solids, this is simply for ease of illustration, and embodiments of these assemblies may be curved, rounded, or otherwise irregularly shaped as dictated by and sometimes inevitable due to the manufacturing processes used to fabricate various components.

In the drawings, a particular number and arrangement of structures and components are presented for illustrative purposes and any desired number or arrangement of such structures and components may be present in various embodiments.

Further, unless otherwise specified, the structures shown in the figures may take any suitable form or shape according to material properties, fabrication processes, and operating conditions.

For convenience, if a collection of drawings designated with different letters are present (e.g., FIGS. 10A-10C), such a collection may be referred to herein without the letters (e.g., as “FIG. 10”). Similarly, if a collection of reference numerals designated with different letters are present (e.g., 112a-112e), such a collection may be referred to herein without the letters (e.g., as “112”).

Various operations may be described as multiple discrete actions or operations in turn in a manner that is most helpful in understanding the claimed subject matter. However, the order of description should not be construed as to imply that these operations are necessarily order dependent. In particular, these operations may not be performed in the order of presentation. Operations described may be performed in a different order from the described embodiment. Various additional operations may be performed, and/or described operations may be omitted in additional embodiments.

### Example Embodiments

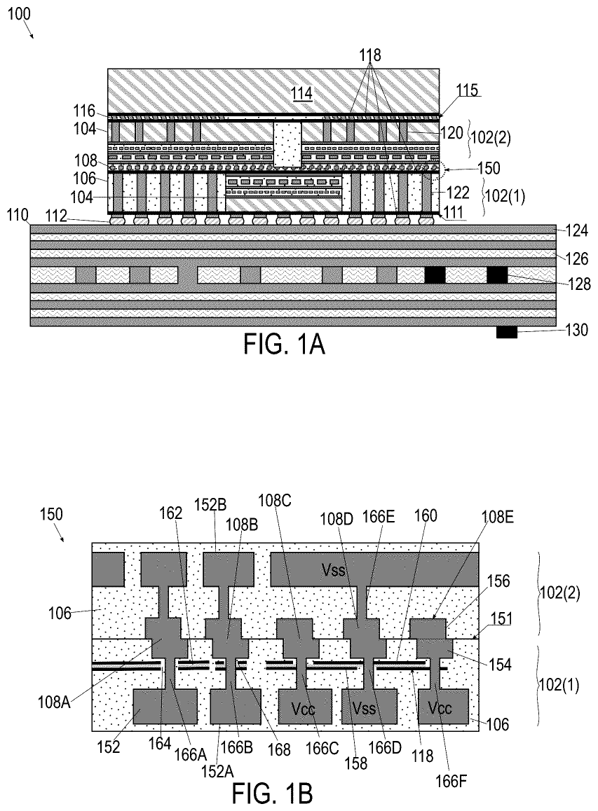

FIG. 1A is a schematic cross-sectional view of an example microelectronic assembly 100 (plural “microelectronic assemblies 100”) according to some embodiments of the present disclosure. Microelectronic assembly 100 comprises a plurality of layers 102 of IC dies 104 in a dielectric material 106, adjacent layers (e.g., 102(1) and 102(2)) in plurality of layers 102 being coupled together by interconnects 108 having a pitch of less than 10 micrometers between adjacent interconnects 108. In some embodiments, each layer 102 may comprise an interface layer (not shown for ease of illustration and so as not to clutter the drawings) on either side of the layer, the interface layer comprising the metal material and dielectric material of interconnects 108. In the example shown in the figure, the number of layers 102 is two: a first layer 102(1) and a second layer 102(2). In various other embodiments, microelectronic assembly 100 may include two or greater number of layers 102. In such embodiments where there are a greater number of layers 102 than shown in the figure, dielectric material 106 may be present around IC dies 104 in one or more such layers 102. In various embodiments, dielectric material 106 comprises inorganic materials, for example, silicon oxide, silicon nitride, silicon carbide, and/or other forms of inorganic dielectric material typically used as interlayer dielectric (ILD) in semiconductor devices.

A package substrate 110 is coupled to a side 111 of plurality of layers 102 by SLIs 112. A support structure 114 is coupled to a side 115 of plurality of layers 102 by interconnects 116, side 115 being opposite to side 111. In some embodiments, support structure 114 may comprise a structurally stiff and thermally conductive base, such as silicon. In various embodiments, support structure 114 may comprise a wafer of silicon cut to suitable proportions to fit over layers 102. Capacitors 118 are present in at least plurality of layers 102 or support structure 114. In various embodiments, capacitors 118 may be planar capacitors, deep trench capacitors and/or via capacitors. In various embodiments, a plurality of capacitors 118 may be conductively coupled in series or in parallel.

In embodiments where capacitors 118 are in support structure 114, such capacitors 118 are connected to plurality of layers 102 by interconnects 116. In some embodiments, one or more IC dies 104 may comprise TSVs 120 conductively coupled to capacitors 118 in support structure 114 by interconnects 116 or directly coupled vias (not shown) from interconnects 116 to capacitors 118 in support structure 114. In some embodiments, through-dielectric vias (TDVs) 122 may be present in dielectric material 106 around IC dies 104 or in between IC dies 104 in various layers 102. TDVs 122 may provide conductive coupling between non-adjacent layers 102 suitably. TSVs 120 and TDVs 122 may be configured to carry power, signals and/or ground connection between package substrate 110 and IC dies 104 in plurality of layers 102. In some embodiments, TDVs 122 may be larger than TSVs 120.

In some embodiments, capacitors 118 comprise planar metal-insulator-metal (MIM) capacitors. The MIM capacitor consists of two parallel metal planes separated by a thin dielectric material. In embodiments (e.g., as shown) where capacitors 118 comprise planar capacitors, capacitors 118 may be in a particular layer 102 (e.g., 102(1)) proximate to an adjacent layer 102 (e.g., 102(2)), for example, in one or more IC dies 104 and/or in dielectric material 106 surrounding IC dies 104; in support structure 114 on a side of support structure 114 proximate to plurality of layers 102; on side 111 of plurality of layers 102; or on side 115 of plurality of layers 102.

In various embodiments, package substrate 110 may comprise conductive traces 124 and organic dielectric material 126. Examples of materials for organic dielectric material 126 are noted in the previous subsection. Note that conductive traces 124 are shown as disconnected rectangles in organic dielectric material 126, such is only for illustrative/schematic purposes and the shapes are not intended to be accurate representations of an actual package substrate. In addition, conductive vias, bond-pads, redistribution layers, substrate cores, passive components and other elements of package substrate 110 are not shown merely for ease of illustration and not as limitations. Package substrate 110 may be coupled to side 111 of plurality of layers 102 by SLIs 112 (e.g., DTPS interconnects, such as flip-chip solder bonds). In various embodiments, SLI 112 may have a pitch greater than 10 micrometers between adjacent interconnects. Some capacitors 128 may be present within package substrate 110, for example, integrated into circuitry therein, disposed in organic dielectric material 126 and conductively coupled suitably to conductive traces 124. Capacitors 130 may also be coupled externally to package substrate 110, for example, by soldering or other processes known in the art.

FIG. 1B is a schematic cross-sectional view of a portion 150 of the example microelectronic assembly of FIG. 1A. Example capacitors 118 are shown disposed proximate to an interface 151 between example layers 102(1) and 102(2). Each layer 102 comprises conductive traces 152, for example, layer 102(1) comprises conductive traces 152A and layer 102(2) comprises conductive traces 152B. Interconnects 108 between layers 102(1) and 102(2) may enable conductive and mechanical coupling between layers 102(1) and 102(2). Note that although a few interconnects 108 is shown, the same structure and description may apply to any other such interconnects comprising hybrid bonds in microelectronic assembly 100 where applicable, for example, interconnects 116.

In a general sense, any interconnect 108, for example interconnect 108E, may comprise, at interface 151 between layers 102(1) and 102(2), metal-metal bonds between bond-pad 154 of layer 102(1) and bond-pad 156 of layer 102(2), and dielectric-dielectric bonds (e.g., oxide-oxide bonds) in dielectric materials 106 of layers 102(1) and 102(2). In some embodiments, the structures as illustrated in the figure may be present in an interface layer between layers 102(1) and 102(2). In other embodiments, the structures as illustrated in the figure may be present in IC dies 104 of the respective layers. In yet other embodiments, some structures as illustrated in the figure may be present in IC dies 104 of one of the layers, and other structures may be present outside/around IC dies 104 of the other one of the layers. Bond-pad 154 of layer 102(1) may bond with bond-pad 156 of layer 102(2). Dielectric material 106 (e.g., silicon oxide, silicon nitride, silicon oxynitride, etc.) in layers 102(1) and 102(2) may bond with each other. The bonded metal and dielectric materials form interconnect 108, comprising hybrid bonds, providing electrical and mechanical coupling between layers 102(1) and 102(2). In various embodiments, interconnects 108 may have a linear dimension of less than 5 micrometers and a pitch of less than 10 micrometers between adjacent interconnects.

Capacitors 118 comprises a conductive structure 158 conductively coupled to one of conductive traces 152 (e.g., 152A), a conductive structure 160 conductively coupled to another one of conductive traces 152 (e.g., 152B), and dielectric material 162 between conductive structures 158 and 160. In some embodiments, conductive structures 158 or 160 may have a thickness ranging between 10 nanometers and 500 nanometers. In various embodiments, conductive structures 158 or 160 may have corrugated shapes. In some embodiments, conductive structures 158 or 160 may be substantially planar. In some embodiments, each of conductive structures 158 and 160 may be comprise multiple layers of different conductive materials. In some embodiments, dielectric material 162 may be of the same (or similar) composition as dielectric material 106. In other embodiments, dielectric material 162 may be of a different composition than dielectric material 106. Examples of dielectric material 162 include hafnium oxide, titanium oxide, etc. In some embodiments, dielectric material 162 may have anisotropic dielectric constant or utilize ferroelectric dielectric materials. Any suitable material to achieve a desired capacitance may be comprised in dielectric material 162 of capacitors 118 within the broad scope of the embodiments.

In some embodiments (not shown) the separate conductive traces 152A and 1528 that are conductively coupled to conductive structures 158 and 160 respectively may be in the same layer 102 (e.g., 102(1) or 102(2)). In some embodiments (not shown) the separate conductive traces 152A and 152B that are conductively coupled to conductive structures 158 and 160 respectively may be in different layers 102 (e.g., 102(1) and 102(2)). In some embodiments, capacitor 118 comprises a planar capacitor having a through hole 164. A conductive via 166 (e.g., 166A) may be disposed through hole 164 and separated from capacitor 118 by dielectric material 106 (or dielectric material 162). In some embodiments, conductive via 166 may be conductively coupled to one of interconnects 108, for example, conductive via 166A is conductively coupled to interconnect 108A as shown in the figure. In other embodiments (not shown) conductive via 166 may conductively couple two or more conductive traces 152 in different levels of dielectric material 106 within the same layer 102.

In some embodiments, capacitor 118 comprises a planar capacitor having a blind hole 168, for example, through conductive structure 160 (and/or dielectric material 162), and not through conductive structure 158. Conductive structure 158 may be conductively coupled to conductive via 166 in some such embodiments. For example, in the embodiment shown in the figure, conductive structure 158 is conductively coupled to conductive via 1668. Conductive via 16613 is conductively coupled to interconnect 108B, which is coupled to conductive traces 152A and 1528 in layers 102(1) and 102(2) respectively. Conductive structure 158 is thus conductively coupled to conductive traces 152A and 1528 through interconnect 108B. In some embodiments, conductive structure 158 is connected to one interconnect 108 by conductive via 166 and conductive structure 160 is connected to another interconnect 108 by another conductive via 166. For example, in the embodiment shown, conductive structure 158 is conductively coupled to interconnect 108C by interconnect 166C, which is connected to conductive trace 152A and conductive structure 160 is conductively coupled to interconnect 108D by conductive via 166D, which is connected to conductive trace 152B; in such embodiment, conductive structure 158 may be coupled to conductive trace 152A in layer 102(1) and conductive structure 160 may be coupled to conductive trace 152B in layer 102(2). In some embodiments, one or more of conductive structures 158 or 160 may be coupled to a floating via 166, which is not conductively coupled to any conductive trace in the layer in which the via is situated, but the floating via may be conductively coupled to one or more interconnects 108, which is conductively coupled to conductive traces in the adjacent layer. In the example embodiment shown in the figure, conductive structure 158 is conductively coupled to conductive vias 166C and 166F, which are coupled to power planes at voltage Vcc in layer 102(1); conductive structure 158 is also conductively coupled to bond-pad 156 in layer 102(2), which is not connected to any conductive trace in layer 102(2). In the example embodiment shown, conductive structure 160 is conductively coupled to ground plane Vss by way of via 166D in layer 102(1) and via 166E in layer 102(2). Note that these example connections are merely shown for ease of illustration and other embodiments of microelectronic assembly 100 may include various other types of conductive coupling between capacitors 118 and conductive traces 152 in one or more layers 102.

Although capacitor 118 is shown as disposed in layer 102(1), this is merely for illustrative purposes and is not a limitation; capacitor 118 may be disposed in layer 102(2) as well (or other layers 102) without departing from the scope of the embodiments. Note that the configurations as shown in the figure may be applicable to other analogous structures also, for example, to capacitors 118 proximate to the interface between support structure 114 and an end layer 102, for example, layer 102(2). Thus, for example, in some embodiments in which support structure 114 may comprise one or more conductive traces 152, one conductive trace 152 may be coupled to one of conductive structures 158 or 160, and another conductive trace 152 in layer 102(2) (or other end layer proximate to support structure 114) may be connected to the other of conductive structures 158 or 160. In some embodiments, both conductive traces 152 coupled to conductive structures 158 or 160 may be in support structure 114. Further, the different configurations of conductive coupling between capacitor 118 and interconnects 108 are merely for example purposes, and in some embodiments, a fewer or greater number and/or variety of such configuration may be present in any one location within microelectronic assembly 100.

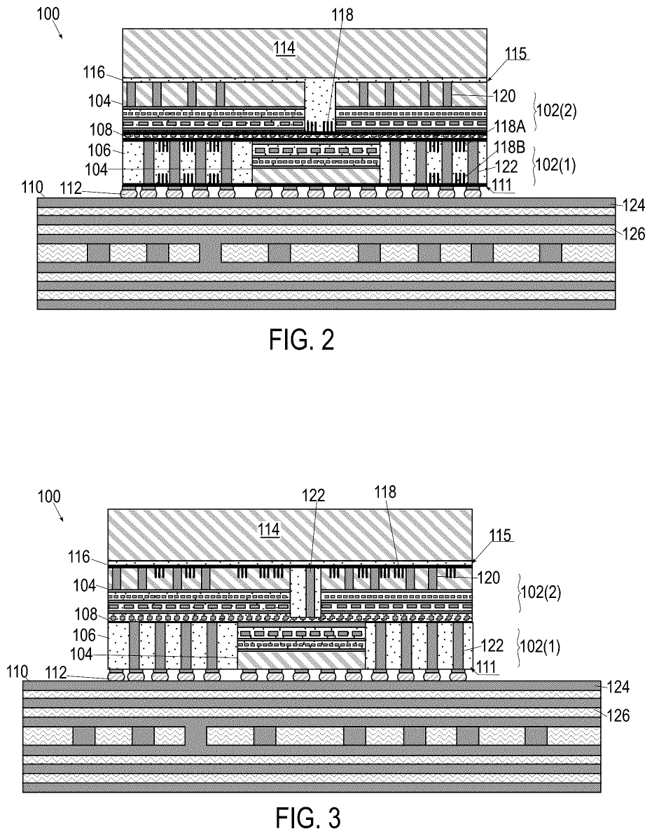

FIG. 2 is a schematic cross-sectional view of another example microelectronic assembly 100 according to some embodiments of the present disclosure. At least some capacitors 118 in microelectronic assembly 100 may comprise deep trench capacitors in dielectric material 106 around IC dies 104 in any one or more layers 102. In the example embodiment shown, capacitors 118 comprising deep trench capacitors are shown located in dielectric material 106 around IC die 104 in layer 102(1) and between IC dies 104 in layer 102(2). Such is merely for ease of illustration and is not intended to be a limitation. Capacitors 118 may be provisioned anywhere in dielectric material 106 in microelectronic assembly 100 within the broad scope of the embodiments. In some embodiments, capacitors 118 may comprise planar capacitors in some portions (e.g., in IC die 104) and deep trench capacitors in other portions (e.g., dielectric material 106) in the same layer 102. In various embodiments, the deep trench capacitors may comprise linear trenches (e.g., having rectangular or square cross-section), circular trenches (e.g., having circular cross-section) or elliptical trenches.

In various embodiments, capacitors 118 comprising deep trench capacitors may have respective depths that are at least ten times larger than respective widths. For example, some deep trench capacitors may have a width of 1 micrometer and a depth (e.g., into dielectric material 106 perpendicular to the width) of 10 micrometers. In some embodiments, capacitors 118 comprising deep trench capacitors may include perovskite materials. The capacitors may also consist of multiple interleaved dielectric and conductive layers, for example, to improve capacitance density and/or support different voltage levels for different circuits in IC dies 104.

In various embodiments, capacitors 118 comprising deep trench capacitors in dielectric material 106 may be fabricated by processes different from those used to fabricate similar capacitors in silicon substrates. For example, atomic layer deposition (ALD) may be used to fabricate capacitors 118 comprising deep trench capacitors in dielectric material 106. Such ALD processes may advantageously result in capacitors 118 free from pin hole defects in dielectric material 162, among other advantages. In some embodiments, during fabrication, layers 102 may be sequentially coupled one over the other. In such embodiments, some capacitors 118 (e.g., 118A) may be formed on a particular one of layers 102 before the next layer 102 is coupled thereto. In such embodiments, some other capacitors (e.g., 118B) may be formed at the end of the assembly process, for example, after forming plurality of layers 102, then turning the fabricated assembly over to expose side 111 and forming capacitors 118B thereon.

FIG. 3 is a schematic cross-sectional view of another example microelectronic assembly 100 according to some embodiments of the present disclosure. At least some capacitors 118 in microelectronic assembly 100 may comprise deep trench capacitors in substrates of IC dies 104 in any one or more layers 102. In the example embodiment shown, capacitors 118 comprising deep trench capacitors are shown located in IC dies 104 in layer 102(2), such is merely for ease of illustration and is not intended to be a limitation. Capacitors 118 may be provisioned anywhere in IC dies 104 in microelectronic assembly 100 within the broad scope of the embodiments. In some embodiments, capacitors 118 may be provisioned on side 115 of plurality of layers 102 and may extend beyond edges of IC dies 104 into dielectric material 106. In some embodiments, capacitors 118 in one layer 102 may be conductively coupled to another layer 102 by TDVs 122 in dielectric material 106. In some embodiments, capacitors 118 may comprise planar capacitors in some portions (e.g., in dielectric material 106) and deep trench capacitors in other portions (e.g., IC dies 104) in the same layer 102.

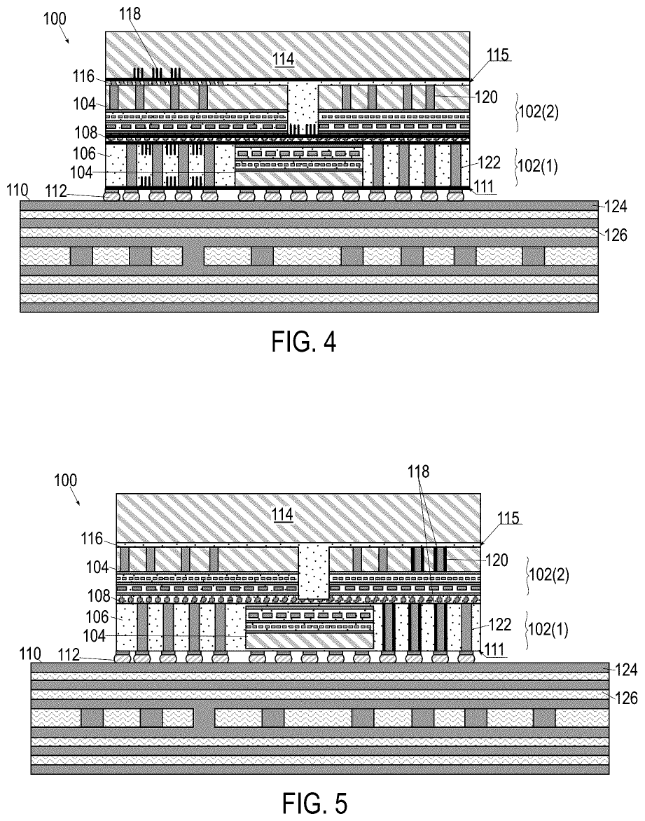

FIG. 4 is a schematic cross-sectional view of another example microelectronic assembly 100 according to some embodiments of the present disclosure. At least some capacitors 118 in microelectronic assembly 100 may be provided in support structure 114. Such capacitors 118 may be conductively coupled to plurality of layers 102 by metal-metal bonds in interconnects 116. Capacitors 118 in structural silicon may comprise planar capacitors and/or deep trench capacitors.

FIG. 5 is a schematic cross-sectional view of another example microelectronic assembly 100 according to some embodiments of the present disclosure. In some embodiments, capacitors 118 may comprise via capacitors located around (or comprised in, forming an integral part of, etc.) TSVs 120 in the respective substrates of IC dies 104 and/or TDVs 122 in dielectric material 106 around IC dies 104. Such via capacitors with high surface area for high capacitance density can provide additional capacitance in microelectronic assembly 100.

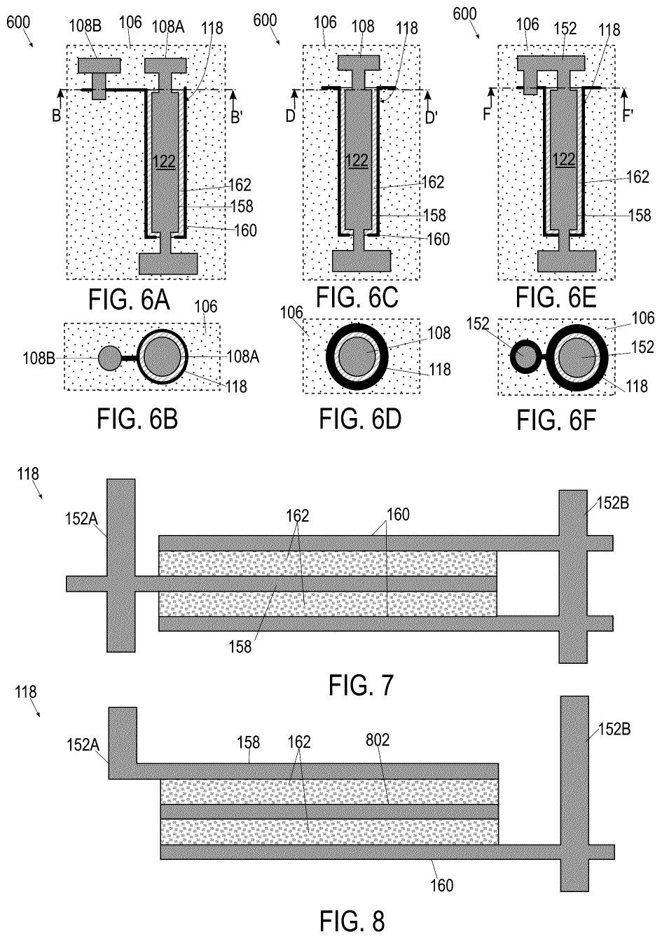

FIGS. 6A-6F are various cross-sectional view of capacitors 118 comprising via capacitors in a portion 600 of microelectronic assembly 100. The examples shown comprise via capacitors associated with TDVs 122; various other embodiments may associate a similar structure with TSVs 120 also. FIG. 6A shows a cross-section taken along a length (or depth) of TDV 122 according to one embodiment of the present disclosure. FIG. 6B shows a cross-section taken along axis BB′ orthogonal to the length (or depth) of TDV 122 of the embodiment shown in FIG. 6A. In some embodiments, capacitors 118 may be disposed as a concentric circular structure centered around TDV 122. In the example shown, conductive structure 158 of capacitor 118 may correspond to TDV 122 conductively coupled to bond-pad 108A; conductive structure 160 may be conductively coupled to another bond-pad 108B (or conductive trace 152 in some embodiments); and dielectric material 162 may be disposed between conductive structures 158 and 160. In an example embodiment, conductive structure 158 may be connected to a first voltage rail (e.g., Vcc) and conductive structure 160 may be connected to another second voltage rail (e.g., Vss). Capacitor 118 may be conductively coupled to conductive traces 152 by a conductive trace (or other structure).

FIG. 6C shows a cross-section taken along a length (or depth) of TDV 122 according to another embodiment of the present disclosure. FIG. 6D shows a cross-section taken along axis DD′ orthogonal to the length (or depth) of TDV 122. In some embodiments, bond-pad 108 may provide conductive coupling to one of conductive structures 158 and 160 as appropriate.

FIG. 6E shows a cross-section taken along a length (or depth) of TDV 122 according to yet another embodiment of the present disclosure. FIG. 6F shows a cross-section taken along axis FF′ orthogonal to the length (or depth) of TDV 122. In some embodiments, one of conductive structures 158 or 160 of the structure that is capacitor 118 in the embodiments of FIGS. 6A-6D, may be conductively coupled to TDV 122 and conductive trace 152. The conductive structure that is analogous to conductive structure 160 of FIGS. 6A-6D may also be shorted to TDV 122 so that it becomes part of conductive structure 158 and is at the same voltage as conductive trace 152.

FIG. 7 is a schematic view of an example configuration of capacitors 118 in microelectronic assembly 100 according to various embodiments of the present disclosure. In various embodiments, conductive structures 158 and 160 may comprise respective pluralities of fingers separated by dielectric material 162 such that capacitors 118 are conductively coupled in parallel. For example, fingers of conductive structures 158 may be conductively coupled to conductive trace 152A at voltage common collector (VCC) (e.g., positive supply voltage), whereas fingers of conductive structures 160 may be conductively coupled to conductive trace 152B at voltage supply source (VSS) (e.g., ground or negative supply voltage). The various fingers may be separated from each other by dielectric material 162.

FIG. 8 is a schematic view of another example configuration of capacitors 118 in microelectronic assembly 100 according to various embodiments of the present disclosure. In various embodiments, capacitors 118 are conductively coupled in series. For example, conductive structure 158 may be conductively coupled to conductive trace 152A at voltage common collector (VCC) (e.g., positive supply voltage), whereas conductive structure 160 may be conductively coupled to conductive trace 152B at voltage supply source (VSS) (e.g., ground or negative supply voltage). Capacitors 118 may comprise other conductive structures 802 that may be arranged parallel to conductive structures 158 and 160 and separated therefrom by dielectric material 162 to enable a series configuration of capacitors 118.

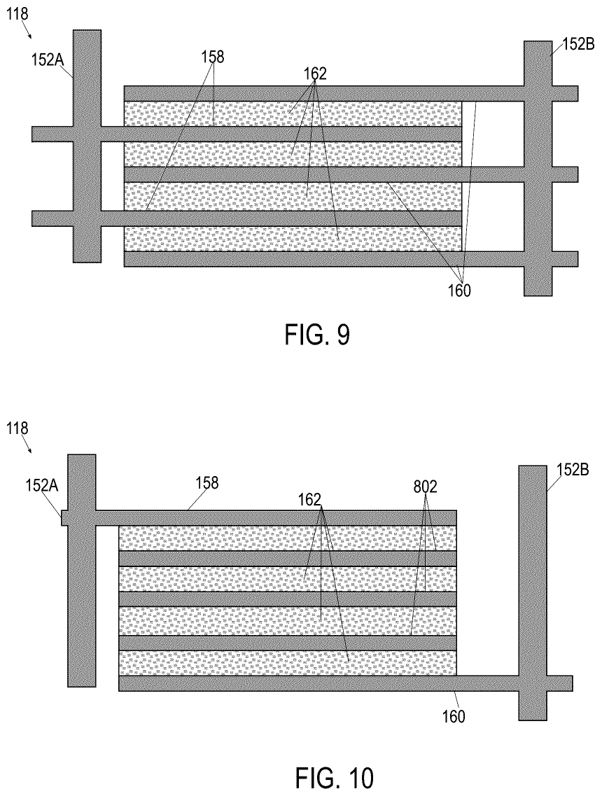

FIG. 9 is a schematic view of another example configuration of capacitors 118 in microelectronic assembly 100 according to various embodiments of the present disclosure. In various embodiments, conductive structures 158 and 160 may comprise respective pluralities of fingers separated by dielectric material 162 such that capacitors 118 are conductively coupled in parallel. For example, fingers of conductive structures 158 may be conductively coupled to conductive trace 152A at voltage common collector (VCC) (e.g., positive supply voltage), whereas fingers of conductive structures 160 may be conductively coupled to conductive trace 152B at voltage supply source (VSS) (e.g., ground or negative supply voltage). Capacitors 118 may also comprise other conductive structures 802 that may be conductively coupled to other voltages to enable a series configuration of capacitors 118. The various fingers and conductive structures of capacitors 118 may be separated from each other by dielectric material 162.

FIG. 10 is a schematic view of another example configuration of capacitors 118 in microelectronic assembly 100 according to various embodiments of the present disclosure. In various embodiments, capacitors 118 are conductively coupled in series. For example, conductive structure 158 may be conductively coupled to conductive trace 152A at voltage common collector (VCC) (e.g., positive supply voltage), whereas conductive structure 160 may be conductively coupled to conductive trace 152B at voltage supply source (VSS) (e.g., ground or negative supply voltage). Capacitors 118 may comprise other conductive structures 802 arranged mutually parallel to each other and separated by dielectric material 162 from each other and from conductive structures 158 and 160 to enable a series configuration of capacitors 118.

In various embodiments, any of the features discussed with reference to any of FIGS. 1-10 herein may be combined with any other features to form a package with one or more IC dies as described herein, for example, to form a modified IC die 104 or a modified microelectronic assembly 100. Some such combinations are described above, but, in various embodiments, further combinations and modifications are possible. Further, the various embodiments described in any of FIGS. 1-10 herein may be combined suitably based on particular needs within the broad scope of the embodiments.

### Example Methods

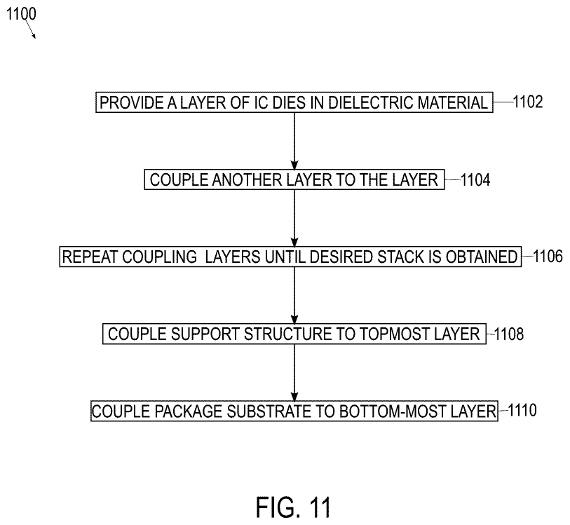

FIG. 11 is a schematic flow diagram illustrating example operations 1100 that may be associated with embodiments of methods to fabricate microelectronic assembly 100. At 1102, layer 102(1) of IC dies 104 in dielectric material 106 may be provided. In various embodiments, providing layer 102 comprises coupling known good IC dies 104 to a carrier, forming copper pillars around IC dies 104, depositing dielectric material 106 around the copper pillars and IC dies 104 such that the copper pillars become TDVs 122, and removing the carrier. In some other embodiments, providing layer 102 comprises: coupling known good IC dies 104 to a carrier, depositing dielectric material 106 around IC dies 104, forming vias in dielectric material 106, depositing conductive material in dielectric material 106 to form TDVs 122, and removing the carrier.

At 1104, another layer 102(2) may be coupled to layer 102(1), layer 102(2) also comprising IC dies 104 surrounded by dielectric material 106. In various embodiments, coupling another layer 102(2) to layer 102(1) comprises forming an interface layer comprising metal-metal bonds and dielectric-dielectric bonds. At 1006, additional layers 102 may be coupled sequentially until a desired stack of layers is obtained. At 1108, support structure 114 may be coupled to a topmost layer in the stack of layers 102. In various embodiments, coupling support structure 114 comprises forming interconnects 116 at an interface layer comprising metal-metal bonds and dielectric-dielectric bonds. Dielectric material 106 may comprise silicon oxide, silicon nitride, silicon carbide, silicon oxycarbonitride, etc. in various embodiments. At least one layer 102 comprises capacitors 118. In various embodiment capacitors 118 may be formed by ALD. Operations 1100 may further comprise coupling package support 110 to a bottom-most layer in the stack of layers 102 opposite to support structure 114. In various embodiments, coupling package support 110 comprises forming SLIs 112 between package substrate 110 and stack of layers 102.

Although FIG. 11 illustrates various operations performed in a particular order, this is simply illustrative and the operations discussed herein may be reordered and/or repeated as suitable. Further, additional processes which are not illustrated may also be performed without departing from the scope of the present disclosure. Also, various ones of the operations discussed herein with respect to FIG. 11 may be modified in accordance with the present disclosure to fabricate others of microelectronic package 100 disclosed herein. Although various operations are illustrated in FIG. 11 once each, the operations may be repeated as often as desired. For example, one or more operations may be performed in parallel to manufacture and test multiple microelectronic packages substantially simultaneously. In another example, the operations may be performed in a different order to reflect the structure of a particular microelectronic package in which one or more substrates or other components as described herein may be included.

Furthermore, the operations illustrated in FIG. 11 may be combined or may include more details than described. For example, the operations may be modified suitably without departing from the scope of the disclosure for IC dies 104 that do not have a semiconductor substrate, but rather, are fabricated on other materials, such as glass or ceramic materials. Still further, the various operations shown and described may further include other manufacturing operations related to fabrication of other components of the microelectronic assemblies described herein, or any devices that may include the microelectronic assemblies as described herein. For example, the operations not shown in FIG. 11 may include various cleaning operations, additional surface planarization operations, operations for surface roughening, operations to include barrier and/or adhesion layers as desired, and/or operations for incorporating microelectronic packages as described herein in, or with, an IC component, a computing device, or any desired structure or device.

### Example Devices and Components

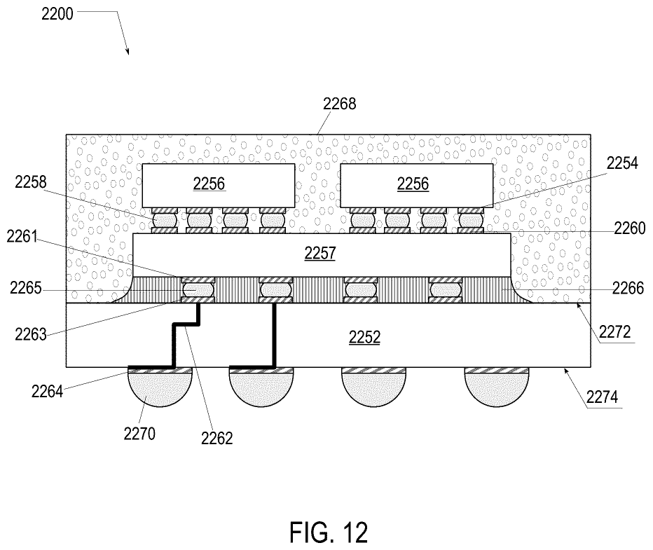

The packages disclosed herein, e.g., any of the embodiments shown in FIGS. 1-11 or any further embodiments described herein, may be included in any suitable electronic component. FIGS. 12-14 illustrate various examples of packages, assemblies, and devices that may be used with or include any of the IC packages as disclosed herein.

FIG. 12 is a side, cross-sectional view of an example IC package 2200 that may include IC packages in accordance with any of the embodiments disclosed herein. In some embodiments, the IC package 2200 may be a SiP.

As shown in the figure, package substrate 2252 may be formed of an insulator (e.g., a ceramic, a buildup film, an epoxy film having filler particles therein, etc.), and may have conductive pathways extending through the insulator between first face 2272 and second face 2274, or between different locations on first face 2272, and/or between different locations on second face 2274. These conductive pathways may take the form of any of the interconnect structures comprising lines and/or vias.

Package substrate 2252 may include conductive contacts 2263 that are coupled to conductive pathway 2262 through package substrate 2252, allowing circuitry within dies 2256 and/or interposer 2257 to electrically couple to various ones of conductive contacts 2264 (or to other devices included in package substrate 2252, not shown).

IC package 2200 may include interposer 2257 coupled to package substrate 2252 via conductive contacts 2261 of interposer 2257, first-level interconnects 2265, and conductive contacts 2263 of package substrate 2252. First-level interconnects 2265 illustrated in the figure are solder bumps, but any suitable first-level interconnects 2265 may be used, such as solder bumps, solder posts, or bond wires.

IC package 2200 may include one or more dies 2256 coupled to interposer 2257 via conductive contacts 2254 of dies 2256, first-level interconnects 2258, and conductive contacts 2260 of interposer 2257. Conductive contacts 2260 may be coupled to conductive pathways (not shown) through interposer 2257, allowing circuitry within dies 2256 to electrically couple to various ones of conductive contacts 2261 (or to other devices included in interposer 2257, not shown). First-level interconnects 2258 illustrated in the figure are solder bumps, but any suitable first-level interconnects 2258 may be used, such as solder bumps, solder posts, or bond wires. As used herein, a “conductive contact” may refer to a portion of electrically conductive material (e.g., metal) serving as an interface between different components; conductive contacts may be recessed in, flush with, or extending away from a surface of a component, and may take any suitable form (e.g., a conductive pad or socket).

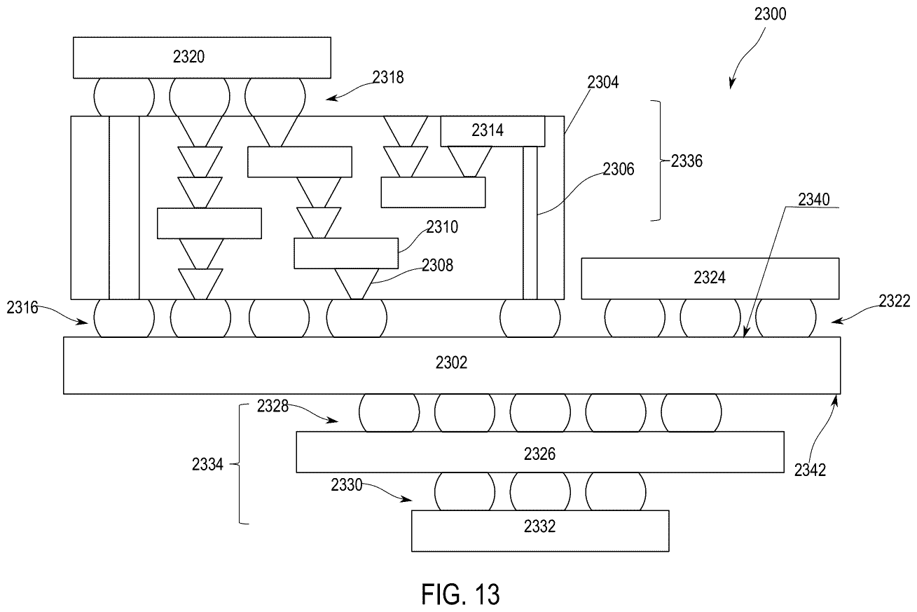

In some embodiments, underfill material 2266 may be disposed between package substrate 2252 and interposer 2257 around first-level interconnects 2265, and mold 2268 may be disposed around dies 2256 and interposer 2257 and in contact with package substrate 2252. In some embodiments, underfill material 2266 may be the same as mold 2268. Example materials that may be used for underfill material 2266 and mold 2268 are epoxies as suitable. Second-level interconnects 2270 may be coupled to conductive contacts 2264. Second-level interconnects 2270 illustrated in the figure are solder balls (e.g., for a ball grid array (BGA) arrangement), but any suitable second-level interconnects 2270 may be used (e.g., pins in a pin grid array arrangement or lands in a land grid array arrangement). Second-level interconnects 2270 may be used to couple IC package 2200 to another component, such as a circuit board (e.g., a motherboard), an interposer, or another IC package, as known in the art and as discussed below with reference to FIG. 13.

In various embodiments, any of dies 2256 may be microelectronic assembly 100 as described herein. In embodiments in which IC package 2200 includes multiple dies 2256, IC package 2200 may be referred to as a multi-chip package (MCP). Dies 2256 may include circuitry to perform any desired functionality. For example, besides one or more of dies 2256 being microelectronic assembly 100 as described herein, one or more of dies 2256 may be logic dies (e.g., silicon-based dies), one or more of dies 2256 may be memory dies (e.g., HBM), etc. In some embodiments, any of dies 2256 may be implemented as discussed with reference to any of the previous figures. In some embodiments, at least some of dies 2256 may not include implementations as described herein.

Although IC package 2200 illustrated in the figure is a flip-chip package, other package architectures may be used. For example, IC package 2200 may be a BGA package, such as an embedded wafer-level ball grid array (eWLB) package. In another example, IC package 2200 may be a wafer-level chip scale package (WLCSP) or a panel fan-out (FO) package. Although two dies 2256 are illustrated in IC package 2200, IC package 2200 may include any desired number of dies 2256. IC package 2200 may include additional passive components, such as surface-mount resistors, capacitors, and inductors disposed over first face 2272 or second face 2274 of package substrate 2252, or on either face of interposer 2257. More generally, IC package 2200 may include any other active or passive components known in the art.

In some embodiments, no interposer 2257 may be included in IC package 2200; instead, dies 2256 may be coupled directly to conductive contacts 2263 at first face 2272 by first-level interconnects 2265.

FIG. 13 is a cross-sectional side view of an IC device assembly 2300 that may include components having one or more microelectronic assembly 100 in accordance with any of the embodiments disclosed herein. IC device assembly 2300 includes a number of components disposed over a circuit board 2302 (which may be, e.g., a motherboard). IC device assembly 2300 includes components disposed over a first face 2340 of circuit board 2302 and an opposing second face 2342 of circuit board 2302; generally, components may be disposed over one or both faces 2340 and 2342. In particular, any suitable ones of the components of IC device assembly 2300 may include any of the one or more microelectronic assembly 100 in accordance with any of the embodiments disclosed herein; e.g., any of the IC packages discussed below with reference to IC device assembly 2300 may take the form of any of the embodiments of IC package 2200 discussed above with reference to FIG. 12.

In some embodiments, circuit board 2302 may be a PCB including multiple metal layers separated from one another by layers of insulator and interconnected by electrically conductive vias. Any one or more of the metal layers may be formed in a desired circuit pattern to route electrical signals (optionally in conjunction with other metal layers) between the components coupled to circuit board 2302. In other embodiments, circuit board 2302 may be a non-PCB package substrate.

As illustrated in the figure, in some embodiments, IC device assembly 2300 may include a package-on-interposer structure 2336 coupled to first face 2340 of circuit board 2302 by coupling components 2316. Coupling components 2316 may electrically and mechanically couple package-on-interposer structure 2336 to circuit board 2302, and may include solder balls (as shown), male and female portions of a socket, an adhesive, an underfill material, and/or any other suitable electrical and/or mechanical coupling structure.

Package-on-interposer structure 2336 may include IC package 2320 coupled to interposer 2304 by coupling components 2318. Coupling components 2318 may take any suitable form depending on desired functionalities, such as the forms discussed above with reference to coupling components 2316. In some embodiments, IC package 2320 may be or include IC package 2200, e.g., as described above with reference to FIG. 12. In some embodiments, IC package 2320 may include at least one microelectronic assembly 100 as described herein. Microelectronic assembly 100 is not specifically shown in the figure in order to not clutter the drawing.

Although a single IC package 2320 is shown in the figure, multiple IC packages may be coupled to interposer 2304; indeed, additional interposers may be coupled to interposer 2304. Interposer 2304 may provide an intervening package substrate used to bridge circuit board 2302 and IC package 2320. Generally, interposer 2304 may redistribute a connection to a wider pitch or reroute a connection to a different connection. For example, interposer 2304 may couple IC package 2320 to a BGA of coupling components 2316 for coupling to circuit board 2302.

In the embodiment illustrated in the figure, IC package 2320 and circuit board 2302 are attached to opposing sides of interposer 2304. In other embodiments, IC package 2320 and circuit board 2302 may be attached to a same side of interposer 2304. In some embodiments, three or more components may be interconnected by way of interposer 2304.

Interposer 2304 may be formed of an epoxy resin, a fiberglass-reinforced epoxy resin, a ceramic material, or a polymer material such as polyimide. In some implementations, interposer 2304 may be formed of alternate rigid or flexible materials that may include the same materials described above for use in a semiconductor substrate, such as silicon, germanium, and other group III-V and group IV materials. Interposer 2304 may include metal interconnects 2308 and vias 2310, including but not limited to TSVs 2306. Interposer 2304 may further include embedded devices 2314, including both passive and active devices. Such devices may include, but are not limited to, capacitors, decoupling capacitors, resistors, inductors, fuses, diodes, transformers, sensors, ESD devices, and memory devices. More complex devices such as radio frequency (RF) devices, power amplifiers, power management devices, antennas, arrays, sensors, and microelectromechanical systems (MEMS) devices may also be formed on interposer 2304. Package-on-interposer structure 2336 may take the form of any of the package-on-interposer structures known in the art.

In some embodiments, IC device assembly 2300 may include an IC package 2324 coupled to first face 2340 of circuit board 2302 by coupling components 2322. Coupling components 2322 may take the form of any of the embodiments discussed above with reference to coupling components 2316, and IC package 2324 may take the form of any of the embodiments discussed above with reference to IC package 2320.

In some embodiments, IC device assembly 2300 may include a package-on-package structure 2334 coupled to second face 2342 of circuit board 2302 by coupling components 2328. Package-on-package structure 2334 may include an IC package 2326 and an IC package 2332 coupled together by coupling components 2330 such that IC package 2326 is disposed between circuit board 2302 and IC package 2332. Coupling components 2328 and 2330 may take the form of any of the embodiments of coupling components 2316 discussed above, and IC packages 2326 and/or 2332 may take the form of any of the embodiments of IC package 2320 discussed above. Package-on-package structure 2334 may be configured in accordance with any of the package-on-package structures known in the art.

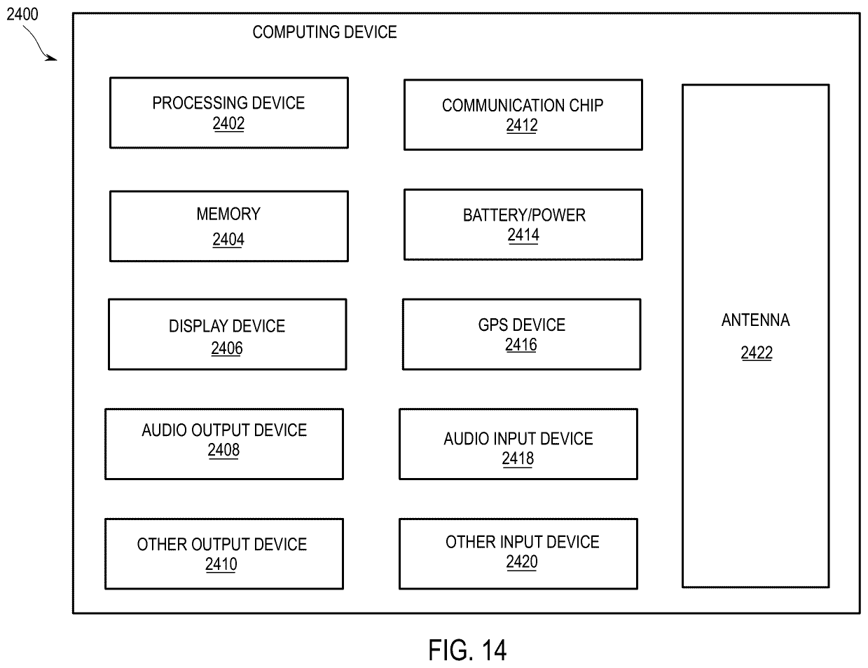

FIG. 14 is a block diagram of an example computing device 2400 that may include one or more components having one or more IC packages in accordance with any of the embodiments disclosed herein. For example, any suitable ones of the components of computing device 2400 may include a microelectronic assembly (e.g., 100) in accordance with any of the embodiments disclosed herein. In another example, any one or more of the components of computing device 2400 may include any embodiments of IC package 2200 (e.g., as shown in FIG. 12). In yet another example, any one or more of the components of computing device 2400 may include an IC device assembly 2300 (e.g., as shown in FIG. 13).

A number of components are illustrated in the figure as included in computing device 2400, but any one or more of these components may be omitted or duplicated, as suitable for the application. In some embodiments, some or all of the components included in computing device 2400 may be attached to one or more motherboards. In some embodiments, some or all of these components are fabricated onto a single SoC die.

Additionally, in various embodiments, computing device 2400 may not include one or more of the components illustrated in the figure, but computing device 2400 may include interface circuitry for coupling to the one or more components. For example, computing device 2400 may not include a display device 2406, but may include display device interface circuitry (e.g., a connector and driver circuitry) to which display device 2406 may be coupled. In another set of examples, computing device 2400 may not include an audio input device 2418 or an audio output device 2408, but may include audio input or output device interface circuitry (e.g., connectors and supporting circuitry) to which audio input device 2418 or audio output device 2408 may be coupled.

Computing device 2400 may include a processing device 2402 (e.g., one or more processing devices). As used herein, the term “processing device” or “processor” may refer to any device or portion of a device that processes electronic data from registers and/or memory to transform that electronic data into other electronic data that may be stored in registers and/or memory. Processing device 2402 may include one or more DSPs, ASICs, CPUs, GPUs, cryptoprocessors (specialized processors that execute cryptographic algorithms within hardware), server processors, or any other suitable processing devices. Computing device 2400 may include a memory 2404, which may itself include one or more memory devices such as volatile memory (e.g., dynamic random access memory (DRAM)), nonvolatile memory (e.g., read-only memory (ROM)), flash memory, solid-state memory, and/or a hard drive. In some embodiments, memory 2404 may include memory that shares a die with processing device 2402. This memory may be used as cache memory and may include embedded dynamic random access memory (eDRAM) or spin transfer torque magnetic random access memory (STT-M RAM).

In some embodiments, computing device 2400 may include a communication chip 2412 (e.g., one or more communication chips). For example, communication chip 2412 may be configured for managing wireless communications for the transfer of data to and from computing device 2400. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

Communication chip 2412 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), LTE project along with any amendments, updates, and/or revisions (e.g., advanced LTE project, ultramobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 2412 may operate in accordance with a Global System for Mobile Communication (GSM), General Packet Radio Service (GPRS), Universal Mobile Telecommunications System (UMTS), High-Speed Packet Access (HSPA), Evolved HSPA (E-HSPA), or LTE network. The communication chip 2412 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). Communication chip 2412 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. Communication chip 2412 may operate in accordance with other wireless protocols in other embodiments. Computing device 2400 may include an antenna 2422 to facilitate wireless communications and/or to receive other wireless communications (such as AM or FM radio transmissions).

In some embodiments, communication chip 2412 may manage wired communications, such as electrical, optical, or any other suitable communication protocols (e.g., the Ethernet). As noted above, communication chip 2412 may include multiple communication chips. For instance, a first communication chip 2412 may be dedicated to shorter-range wireless communications such as Wi-Fi or Bluetooth, and a second communication chip 2412 may be dedicated to longer-range wireless communications such as global positioning system (GPS), EDGE, GPRS, CDMA, WiMAX, LTE, EV-DO, or others. In some embodiments, a first communication chip 2412 may be dedicated to wireless communications, and a second communication chip 2412 may be dedicated to wired communications.

Computing device 2400 may include battery/power circuitry 2414. Battery/power circuitry 2414 may include one or more energy storage devices (e.g., batteries or capacitors) and/or circuitry for coupling components of computing device 2400 to an energy source separate from computing device 2400 (e.g., AC line power).

Computing device 2400 may include a display device 2406 (or corresponding interface circuitry, as discussed above). Display device 2406 may include any visual indicators, such as a heads-up display, a computer monitor, a projector, a touchscreen display, a liquid crystal display (LCD), a light-emitting diode display, or a flat panel display, for example.

Computing device 2400 may include audio output device 2408 (or corresponding interface circuitry, as discussed above). Audio output device 2408 may include any device that generates an audible indicator, such as speakers, headsets, or earbuds, for example.

Computing device 2400 may include audio input device 2418 (or corresponding interface circuitry, as discussed above). Audio input device 2418 may include any device that generates a signal representative of a sound, such as microphones, microphone arrays, or digital instruments (e.g., instruments having a musical instrument digital interface (MIDI) output).

Computing device 2400 may include a GPS device 2416 (or corresponding interface circuitry, as discussed above). GPS device 2416 may be in communication with a satellite-based system and may receive a location of computing device 2400, as known in the art.

Computing device 2400 may include other output device 2410 (or corresponding interface circuitry, as discussed above). Examples of other output device 2410 may include an audio codec, a video codec, a printer, a wired or wireless transmitter for providing information to other devices, or an additional storage device.

Computing device 2400 may include other input device 2420 (or corresponding interface circuitry, as discussed above). Examples of other input device 2420 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

Computing device 2400 may have any desired form factor, such as a handheld or mobile computing device (e.g., a cell phone, a smart phone, a mobile internet device, a music player, a tablet computer, a laptop computer, a netbook computer, an ultrabook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device. In some embodiments, computing device 2400 may be any other electronic device that processes data.

### Select Examples

Example 1 provides a microelectronic assembly (e.g., 100, FIG. 1A), comprising: a plurality of layers (e.g., 102) of IC dies (e.g., 104) in a dielectric material (e.g., 106), adjacent layers in the plurality of layers being coupled together by first interconnects (e.g., 108) having a pitch of less than 10 micrometers between adjacent first interconnects; a package substrate (e.g., 110) coupled to a first side (e.g., 111) of the plurality of layers by second interconnects (e.g., 112); a support structure (e.g., 114) coupled to a second side (e.g., 115) of the plurality of layers by third interconnects (e.g., 116), the second side being opposite to the first side; and capacitors (e.g., 118) in at least the plurality of layers or the support structure, in which the capacitors are selected from at least planar capacitors, deep trench capacitors and via capacitors.

Example 2 provides the microelectronic assembly of example 1, in which a plurality of capacitors is conductively coupled in series or in parallel.

Example 3 provides the microelectronic assembly of any one of examples 1-2, in which the capacitors in the support structure are connected to the plurality of layers by the third interconnects.

Example 4 provides the microelectronic assembly of example 3, in which at least one IC die proximate to the support structure comprises TSVs (e.g., 120) conductively coupled to the capacitors in the support structure by the third interconnects.

Example 5 provides the microelectronic assembly of any one of examples 1-4, in which the capacitors in IC dies proximate to the support structure are conductively coupled to IC dies proximate to the package substrate by TSVs and directly coupled vias.

Example 6 provides the microelectronic assembly of any one of examples 1-5, in which the planar capacitors comprise MIM capacitors.

Example 7 provides the microelectronic assembly of any one of examples 1-6, in which any of the planar capacitors is at least in: one of the plurality of layers, proximate to an adjacent layer in the plurality of layers, the support structure, proximate to the plurality of layers, on the first side of the plurality of layers, or on the second side of the plurality of layers.

Example 8 provides the microelectronic assembly of any one of examples 1-7, in which (e.g., FIG. 1B) any one of the capacitors comprises: a first conductive structure (e.g., 158) conductively coupled to a first conductive trace (e.g., 152A), a second conductive structure (e.g., 160) conductively coupled to a second conductive trace (e.g., 152B), and another dielectric material (e.g., 162) between the first conductive structure and the second conductive structure.

Example 9 provides the microelectronic assembly of example 8, in which: the first conductive trace is in one layer of the plurality of layers, the second conductive trace is in another layer of the plurality of layers, and the one layer is adjacent to the another layer.

Example 10 provides the microelectronic assembly of example 8, in which the first conductive trace and the second conductive trace are in one layer of the plurality of layers.

Example 11 provides the microelectronic assembly of example 8, in which: the first conductive trace is in the support structure, the second conductive trace is in one layer of the plurality of layers, and the support structure is adjacent to the one layer.

Example 12 provides the microelectronic assembly of example 8, in which the first conductive trace and the second conductive trace are in the support structure.

Example 13 provides the microelectronic assembly of any one of examples 7-12, in which (e.g., FIG. 1B): at least one of the capacitors comprises a planar capacitor with a hole (e.g., 164), a conductive via (e.g., 166) in the hole is separated from the at least one planar capacitor by the dielectric material, and the conductive via is conductively coupled to one of the first interconnects (e.g., 108A).

Example 14 provides the microelectronic assembly of any one of examples 7-12, in which: at least one of the capacitors comprises a planar capacitor with a hole, a conductive via in the hole is separated from the at least one planar capacitor by the dielectric material, and the conductive via is conductively coupled to one of the third interconnects.

Example 15 provides the microelectronic assembly of any one of examples 8-14, in which the first conductive structure and the second conductive structure have a thickness ranging between 10 nanometers and 100 nanometers.

Example 16 provides the microelectronic assembly of any one of examples 8-15, in which the first conductive structure and the second conductive structure have corrugated shapes.

Example 17 provides the microelectronic assembly of any one of examples 8-16, in which the another dielectric material is selected from: a compound comprising oxygen and at least one of hafnium and titanium.

Example 18 provides the microelectronic assembly of any one of examples 8-17, in which the another dielectric material has anisotropic dielectric constant.

Example 19 provides the microelectronic assembly of any one of examples 1-18, in which the deep trench capacitors are in at least one of: the dielectric material around the IC dies (e.g., FIG. 2), one or more IC dies (e.g., FIG. 3), or the support structure (e.g., FIG. 4).

Example 20 provides the microelectronic assembly of example 19, in which the deep trench capacitors are linear trenches.

Example 21 provides the microelectronic assembly of example 19, in which the deep trench capacitors have a circular cross-section or a square cross-section.

Example 22 provides the microelectronic assembly of any one of examples 19-21, in which the deep trench capacitors have respective depths that are at least ten times larger than respective widths.

Example 23 provides the microelectronic assembly of any one of examples 19-22, in which at least one trench capacitor has a depth of 10 micrometers and a width of 1 micrometer.

Example 24 provides the microelectronic assembly of any one of examples 19-23, in which the deep trench capacitors comprise perovskite materials.

Example 25 provides the microelectronic assembly of any one of examples 19-24, in which the deep trench capacitors comprise multi-layer ALD structures and another dielectric material that is free of pin-holes.

Example 26 provides the microelectronic assembly of any one of examples 19-25, in which the deep trench capacitors in the one or more IC dies are in respective substrates of the one of more IC dies.

Example 27 provides the microelectronic assembly of any one of examples 1-26, in which the via capacitors are located at least in one of the following locations (e.g., FIG. 5): in one or more IC dies, or in the dielectric material around the IC dies.

Example 28 provides the microelectronic assembly of example 27, in which the via capacitors in the one or more IC dies comprise TSVs in respective substrates of the one or more IC dies.

Example 29 provides the microelectronic assembly of example 27, in which the via capacitors in the one or more IC dies comprise TDVs (e.g., 122) in the dielectric materials.

Example 30 provides the microelectronic assembly of any one of examples 1-29, in which (e.g., FIG. 1B) the first interconnects comprise hybrid bonds having metal-metal bonds and dielectric-dielectric bonds.

Example 31 provides the microelectronic assembly of any one of examples 1-30, in which the second interconnects comprise SLIs.

Example 32 provides the microelectronic assembly of any one of examples 1-31, in which the third interconnects comprise at least one of: hybrid bonds having metal-metal bonds and dielectric-dielectric bonds, or dielectric-dielectric bonds.

Example 33 provides the microelectronic assembly of any one of examples 1-32, in which the package substrate comprises conductive traces (e.g., 124) and an organic dielectric material (e.g., 126).

Example 34 provides the microelectronic assembly of any one of examples 1-33, further comprising capacitors (e.g., 128) in the package substrate.

Example 35 provides the microelectronic assembly of any one of examples 1-34, further comprising capacitors (e.g., 130) coupled to a surface of the package substrate.

Example 36 provides the microelectronic assembly of any one of examples 1-35, in which the structural support comprises silicon.

Example 37 provides an IC package, comprising: a first layer (e.g., 102(1)) of IC dies (e.g., 104) in a dielectric material (e.g., 106); a second layer (e.g., 102(2)) of IC dies in the dielectric material; a package substrate (e.g., 110) coupled to the first layer; a support structure (e.g., 114) couple to the second layer; and capacitors (e.g., 118) in at least the first layer, the second layer, or the support structure, in which: the first layer and the second layer are coupled by FLI's (e.g., 108) having a first pitch less than 10 micrometers between adjacent FLIs, the package substrate is coupled to the first layer by SLI (e.g., 112) having a second pitch greater than 10 micrometers between adjacent SLIs, the support structure is coupled to the second layer by other FLI's (e.g., 116) having a third pitch less than 10 micrometers between adjacent FLIs, and the capacitors are selected from at least planar capacitors, deep trench capacitors and via capacitors.

Example 38 provides the IC package of example 37, in which the capacitors are proximate to the package substrate in the first layer.

Example 39 provides the IC package of example 37, in which the capacitors are proximate to the support structure in the second layer.

Example 40 provides the IC package of example 37, in which the capacitors are proximate to an interface between the first layer and the second layer.

Example 41 provides the IC package of any one of examples 37-40, in which: the capacitors comprise a first conductive structure (e.g., 158), a second conductive structure (e.g., 160), and a capacitor-dielectric material (e.g., 162) between the first conductive structure and the second conductive structure, the first conductive structure is configured to be coupled to a power source, and the second conductive structure is configured to be coupled to a ground connection.

Example 42 provides the IC package of example 41, in which: at least one FLI between the first layer and the second layer is coupled to the power source, the first conductive structure is coupled to the at least one FLI, at least another FLI between the first layer and the second layer is coupled to the ground connection, and the first conductive structure is coupled to the at least another FLI.

Example 43 provides the IC package of example 43, in which the power source is conductively directly coupled to the second layer and the ground connection is conductively directly coupled to the first layer.

Example 44 provides the IC package of example 43, in which the power source and the ground connection are conductively directly coupled to the first layer.

Example 45 provides the IC package of example 43, in which the power source and the ground connection are conductively directly coupled to the second layer.

Example 46 provides the IC package of any one of examples 41-45, in which the first conductive structure and the second conductive structure comprise respective pluralities of fingers separated by the capacitor-dielectric material such that the capacitors are conductively coupled in parallel.

Example 47 provides the IC package of any one of examples 41-45, in which the first conductive structure and the second conductive structure comprise respective pluralities of fingers separated by the capacitor-dielectric material such that the capacitors are conductively coupled in series.

Example 48 provides the IC package of any one of examples 41-47, in which the first conductive structure and the second conductive structure comprise planar plates.

Example 49 provides the IC package of any one of examples 41-47, in which the first conductive structure and the second conductive structure comprise corrugated plates.

Example 50 provides the IC package of any one of examples 41-47, in which the first conductive structure and the second conductive structure comprise concentric cylindrical vias.

Example 51 provides the IC package of example 50, in which the cylindrical vias are around TSVs in the IC dies of at least the first layer or the second layer.

Example 52 provides the IC package of example 50, in which the cylindrical vias are around TDVs in the dielectric material of at least the first layer or the second layer.

Example 53 provides the IC package of any one of examples 41-52, in which the first conductive structure and the second conductive structure comprise deep trench vias.

Example 54 provides the IC package of example 53, in which the deep trench vias are in respective substrates of the IC dies in at least the first layer or the second layer.

Example 55 provides the IC package of example 53, in which the deep trench vias are in the dielectric material of at least the first layer or the second layer.

Example 56 provides the IC package of example 53, in which the deep trench vias are in the support structure.

Example 57 provides a method, comprising: providing a layer comprising IC dies surrounded by a dielectric material; coupling another layer to the layer, the another layer comprising IC dies surrounded by the dielectric material; repeating coupling layers until a stack of layers is obtained; and coupling a support structure to a topmost layer in the stack of layers, in which: the dielectric material comprises a compound of silicon and at least one of oxygen, nitrogen and carbon, and at least one of the layers or the support structure comprises capacitors.

Example 58 provides the method of example 57, in which providing the layer comprises: coupling known good IC dies to a carrier; forming copper pillars around the IC dies; depositing the dielectric material around the copper pillars and the IC dies; and removing the carrier.

Example 59 provides the method of example 57, in which providing the layer comprises: coupling known good IC dies to a carrier; depositing the dielectric material around the IC dies; forming vias in the dielectric material; depositing conductive material in the dielectric material to form the TDVs; and removing the carrier.

Example 60 provides the method of any one of examples 57-59, further comprising coupling a package support to a bottom-most layer in the stack of layers opposite to the support structure.

Example 61 provides the method of example 60, in which coupling the package support comprises forming SLIs between the package substrate and the stack of layers.

Example 62 provides the method of any one of examples 57-61, in which coupling another layer to the layer comprises forming an interface layer comprising metal-metal bonds and dielectric-dielectric bonds.

Example 63 provides the method of any one of examples 57-62, in which coupling the support structure comprises forming an interface layer comprising metal-metal bonds and dielectric-dielectric bonds.

Example 64 provides the method of any one of examples 57-63, in which: the support structure comprises silicon, and the capacitors in the support structure comprise MIM capacitor in silicon.

Example 65 provides the method of any one of examples 57-64, in which the capacitors are formed in at least one of the layers or the support structure by ALD.

The above description of illustrated implementations of the disclosure, including what is described in the abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

1. A microelectronic assembly, comprising:
a plurality of layers of IC dies in a dielectric material, adjacent layers in the plurality of layers being coupled together by first interconnects having a pitch of less than 10 micrometers between adjacent first interconnects;
a package substrate coupled to a first side of the plurality of layers by second interconnects;
a support structure coupled to a second side of the plurality of layers by third interconnects, the second side being opposite to the first side; and
capacitors in at least the plurality of layers or the support structure,
wherein the capacitors are selected from at least planar capacitors, deep trench capacitors and via capacitors.

2. The microelectronic assembly of claim 1, wherein any of the planar capacitors is at least in:
one of the plurality of layers, proximate to an adjacent layer in the plurality of layers,
the support structure, proximate to the plurality of layers,
on the first side of the plurality of layers, or
on the second side of the plurality of layers.

3. The microelectronic assembly of claim 1, wherein any one of the capacitors comprises:
a first conductive structure conductively coupled to a first conductive trace,
a second conductive structure conductively coupled to a second conductive trace, and
another dielectric material between the first conductive structure and the second conductive structure.

4. The microelectronic assembly of claim 3, wherein:
the first conductive trace is in one layer of the plurality of layers,
the second conductive trace is in another layer of the plurality of layers or the support structure, and
the one layer is adjacent to the another layer or the support structure.

5. The microelectronic assembly of claim 3, wherein the first conductive trace and the second conductive trace are in at least one of:
one layer of the plurality of layers, or
the support structure.

6. The microelectronic assembly of claim 3, wherein the another dielectric material is selected from: a compound comprising oxygen and at least one of hafnium and titanium.

7. The microelectronic assembly of claim 1, wherein the deep trench capacitors are in at least one of:
the dielectric material around the IC dies,
one or more IC dies, or
the support structure.

8. The microelectronic assembly of claim 1, wherein:
the first interconnects comprise hybrid bonds having metal-metal bonds and dielectric-dielectric bonds, and
the third interconnects comprise at least one of:
hybrid bonds having metal-metal bonds and dielectric-dielectric bonds, or dielectric-dielectric bonds.

9. An IC package, comprising:
a first layer of IC dies in a dielectric material;
a second layer of IC dies in the dielectric material;
a package substrate coupled to the first layer;
a support structure coupled to the second layer; and
capacitors in at least the first layer, the second layer, or the support structure,
wherein:
the first layer and the second layer are coupled by first-level interconnects (FLIs) having a first pitch less than 10 micrometers between adjacent FLIs,
the package substrate is coupled to the first layer by second-level interconnects (SLI) having a second pitch greater than 10 micrometers between adjacent SLIs,
the support structure is coupled to the second layer by other FLIs having a third pitch less than 10 micrometers between adjacent FLIs, and
the capacitors are selected from at least planar capacitors, deep trench capacitors and via capacitors.

10. The IC package of claim 9, wherein the capacitors are proximate to at least one of:
the package substrate in the first layer,
the support structure in the second layer, or
an interface between the first layer and the second layer.

11. The IC package of claim 9, wherein:
the capacitors comprise a first conductive structure, a second conductive structure, and a capacitor-dielectric material between the first conductive structure and the second conductive structure,
the first conductive structure is configured to be coupled to a power source, and
the second conductive structure is configured to be coupled to a ground connection.

12. The IC package of claim 11, wherein the first conductive structure and the second conductive structure comprise respective pluralities of fingers separated by the capacitor-dielectric material such that the capacitors are conductively coupled in parallel or series.

13. The IC package of claim 11, wherein the first conductive structure and the second conductive structure comprise at least one of planar plates or corrugated plates.

14. The IC package of claim 11, wherein:
the first conductive structure and the second conductive structure comprise concentric cylindrical vias, and
the concentric cylindrical vias are around at least one of:
TSVs in the IC dies of at least the first layer or the second layer, or
TDVs in the dielectric material of at least the first layer or the second layer.

15. The IC package of claim 11, wherein:
the first conductive structure and the second conductive structure comprise deep trench vias, and
the deep trench vias are in at least one of:
respective substrates of the IC dies in at least the first layer or the second layer,
the dielectric material of at least the first layer or the second layer, or
the support structure.

16. A method, comprising:
providing a layer comprising IC dies surrounded by a dielectric material;
coupling another layer to the layer, the another layer comprising IC dies surrounded by the dielectric material;
repeating coupling layers until a stack of layers is obtained; and
coupling a support structure to a topmost layer in the stack of layers,
wherein:
the dielectric material comprises a compound of silicon and at least one of oxygen, nitrogen and carbon, and
at least one of the layers or the support structure comprises capacitors.

17. The method of claim 16, wherein providing the layer comprises:
coupling known good IC dies to a carrier;
forming copper pillars around the IC dies;
depositing the dielectric material around the copper pillars and the IC dies; and
removing the carrier.

18. The method of claim 16, further comprising coupling a package support to a bottom-most layer in the stack of layers opposite to the support structure.

19. The method of claim 16, wherein coupling another layer to the layer comprises forming an interface layer comprising metal-metal bonds and dielectric-dielectric bonds.

20. The method of claim 16, wherein:
the support structure comprises silicon, and
the capacitors in the support structure comprise metal-insulator-metal (MIM) capacitors in silicon.
